(19) United States
(12) Patent Application Publication
(10) Pub. No.: US 2023/0057141 A1
(43) Pub. Date: Feb. 23, 2023

(54) Inflatable Non-Imaging concentrator photonic crystal solar spectrum splitter perovskite integrated circuit concentrating photovoltaic system

(71) Applicant: Yonghua Wang, Klamath Falls, OR (US)

(72) Inventor: Yonghua Wang, Klamath Falls, OR (US)

(21) Appl. No.: 17/300,574

(22) Filed: Aug. 23, 2021

(51) Int. Cl. H02S 40/22; G02B 6/02; G02B 6/42; G02B 19/00

(52) U.S. Cl. CPC H02S 40/22; G02B 6/02328; G02B 6/4298; G02B 19/0042; G02B 19/0076; G02B 19/0009

(57) ABSTRACT

A Concentrating PhotoVoltaic (CPV) system employs an inflatable non-imaging CPC concentrator to concentrate sunlight to realize extremely low cost and a synergistically combined photonic crystal waveguide solar spectrum splitter and perovskite integrated circuitry solar cell package to realize ultra-high conversion efficiency of solar radiation. The corporation of band gap variable perovskite materials into the integrated circuit solar cell not only reduces the cost and raises the efficiency of the photovoltaic package as the receiver, but also addresses the unstable issue of the perovskite materials through sealing the perovskite materials into package to prevent moisture, reducing the heat generation to low the temperature, and filtering the UV light and channel to other elemental solar made of broader band gap photovoltaic materials.

### TECHNICAL FIELD

The present disclosure relates generally to Concentrating PhotoVoltaic (CPV) system, more specifically, to inflatable non-imaging concentrator based photonic crystal solar spectrum splitter supported perovskite integrated circuitry solar cell CPV system.

### BACKGROUND

“The sun provides Earth with as much energy every hour as human civilization uses every year. If you are a solar-energy enthusiast, that says it all. No other energy supply could conceivably be as plentiful as the 120,000 terawatts the sun provides ceaselessly and unbidden. If the tiniest fraction of that sunlight were to be captured by photovoltaic cells that turn it straight into electricity, there would be no need to emit any greenhouse gases from any power plant.” (Oliver Morton, Nature, 443, 19-22 (2006)). However, relative to the tremendous potential of solar energy resource, so far, solar energy only contributes less than 3% of electricity in United States. Not far to seek, the unexpected fact is caused by the low efficiency and the high cost of the current photovoltaic technologies. In general, the low efficiency and high cost of the current photovoltaic technologies stem mainly from the intuitive nature of solar radiation and the current approach of the photovoltaic technologies. Solar radiation is featured with a broad spectrum spanning from photon energy 0.25 eV to 4 eV and low energy current density with the standard value 1000 w/m². The current approaches in converting the broad solar spectrum include the single junction solar cell made of semiconductor with fixed band gap, in which, the energy of the incident photon group with photon energy less than the band gap of the semiconductor is lost due to the non-sufficient photon energy to excite electron-hole pairs, and a fraction of the energy of the incident photon group with photon energy away higher than the band gap of the semiconductor due to the thermo-relaxation of exited electron-hole pairs, the total energy losses of the two energy loss mechanism occupies about 50% of the total incident energy, and the multi junction solar cell made of semiconductors with multiple band gaps, in which, the incident photon groups with photon energy matched with the individual band gaps of the semiconductor are absorbed and converted by the band gap matched semiconductors respectively, in this case its performance is limited by the interference of the semiconductors. Although the multi-junction approach realizes remarkable high conversion efficiency, the complexity of fabrication and limited candidates of band gap matched and lattice matched semiconductors make this type of solar cells prohibitively expensive for territory application. The low energy current density of solar radiation requires large area of solar collector to collect enough sunlight to generate power. The current flat plate photovoltaic panel approach, which directly employs large area panel made of expensive semiconductor to collect and convert solar radiation, makes the flat plate photovoltaic technology expensive. Even though, there is current Concentrating Photovoltaic (CPV) approach which employs solar concentrator to condense solar radiation and reduce the area of receiver, the conventional concentrator is still too expensive to radically reduce the cost of CPV system.

In order to release the incredible great potential of solar energy, transformative new approaches in exploration of solar energy must be invented to dramatically reduce the cost, and substantially raise the efficiency of solar energy technology. Up to the present, the CPV approach is approved the most effective one in dramatically reducing the cost of the solar systems. However, the current concentrating mechanisms need transformative alternation and the solar concentrator device design needs disruptive variation. Among the approaches in addressing the energy loss due to the broad band solar radiation, the multi junction solar cell approach still appears to be the most effective method. However, the current tandem cell approach needs radical transformation to effectively eliminate the interference between junctions.

Relative to the current CPV systems that employs solar concentrators made of rigid materials and most likely the tandem solar cells as receiver, the present invention discloses a CPV system with an inflatable non-imaging solar concentrator and an integrated circuitry solar cells made of band gap variable photovoltaic materials such as perovskite materials, CuInGaSe₂ (CIGS) materials, and other materials, as the receiver, which is supported by a photonic crystal solar spectrum splitter to splice the concentrated broad band solar radiation into components and channel those spliced components onto the band gap matched elemental solar cells of the integrated circuitry solar cells.

In particular of perovskite solar cells, even though it demonstrates its game changing potential due to its low cost, simple solution fabrication process, and high conversion efficiency, it is challenged by its non-stability. (Yang Yang, Jingbi You, Make perovskite solar cells stable, Nature, Vol 544, P155, Apr. 13 2017). The non-stability of the perovskite solar cells is mainly caused by moisture, temperature, and UV light. The approach of the present invention effectively filters out the UV light and channels it to other elemental solar cells of the integrated circuitry solar cells; prevents the moisture by packing the integrated circuitry solar cells into a package; and keeps the solar cells at low temperature by reducing the heat generation through spectrum splitting. Therefore, the present invention synergistically leverages the advantage of perovskite solar cells and effectively mitigates its disadvantage.

The objective of the present invention is to employ the inflatable non-imaging solar concentrator to dramatically reduce the cost of the CPV system, the photonic crystal spectrum splitter to splice the concentrated broad band solar spectrum, and the integrated circuitry solar cells made of band gap matched photovoltaic materials to convert the spliced solar spectrum components with ultra-high conversion efficiency.

In particular, the objective of the present invention is also to address the issue of non-stability of perovskite solar cells by preventing the moisture, avoiding high temperature, and filtering UV light.

### SUMMARY

According to the present invention, a CPV system comprises an inflatable non-imaging concentrator, a photonic crystal solar spectrum splitter, and an integrated circuitry solar cell. Wherein, the inflatable non-imaging solar concentrator is made of thin and light membrane and inflated into a non-imaging Compound Parabolic Concentrator (CPC) which has no any other support materials but still possesses enough mechanical strength as a whole body to against wind load. This type of concentrator is not only able to concentrate beam light, but also able to concentrate diffuse light. This type of concentrator consumes very limited materials to realize large scale condensation of solar radiation and therefore reduces the cost of CPV to extremely low level. The photonic crystal solar spectrum splitter is made of photonic crystal waveguides specified to confine different components of solar spectrum. The integrated circuitry solar cell is made of elemental solar cells which are fabricated with band gap matched semiconductor materials relative to the spliced solar spectrum components. When in operation, the incident sunlight including beam light and diffuse light is concentrated by the inflatable non-imaging solar concentrator; the concentrated sunlight is coupled into the photonic crystal solar spectrum splitter and get spliced into its components; the components are channeled onto the element solar cells of the integrated circuitry solar; the element solar cells accept their band gap matched components of solar spectrum to convert them into electricity in ultra-high efficiency.

Through incorporating the low cost high efficiency perovskite elemental solar cells into the integrated circuitry solar cells as the receiver of the CPV system, the present invention is not only able to further reduce cost and raise the efficiency of the entire system, but also able to address the issue of non-stability of perovskite solar cells.

Further aspects and advantages of the present invention will become apparent upon consideration of the following description thereof, reference being made of the following drawing.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 is a schematic structure of the inflatable non-imaging concentrator photonic crystal solar spectrum splitter integrated circuitry solar cell based CPV system.

FIG. 2 is the 3D view of the inflatable non-imaging solar concentrator with photonic crystal solar spectrum splitter and integrated circuitry solar cell package.

FIG. 3 is the indication of the inflatable non-imaging solar concentrator work principle in concentrating both beam light and diffuse light.

FIG. 4 is the schematic indication of the work principle of the photonic crystal waveguide solar spectrum splitter.

FIG. 5 is a schematic indication of the work principle of the integrated circuitry solar cell.

FIG. 6 is a schematic indication of the structure of the integrated circuitry solar cell.

FIG. 7 is a schematic indication of the coupling of the spliced solar spectrum components onto the elemental solar cells of the integrated circuitry solar cells.

### DETAILED DESCRIPTION

Reference will now be made in detail to the present exemplary embodiments, examples of which are illustrated in the accompanying drawings. Wherever possible, the same reference numbers will be used throughout the drawings to refer to the same or like parts.

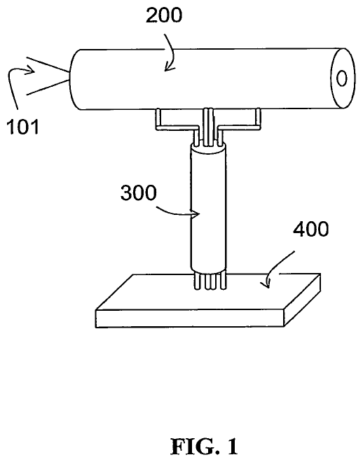

Referring to FIG. 1, the sunlight 101 concentrated by the inflatable non-imaging solar concentrator of the present invention is coupled into the photonic crystal solar spectrum splitter 200, and transmitted by the transmission cable 300, then coupled to the integrated circuitry solar cell packed in the package 400.

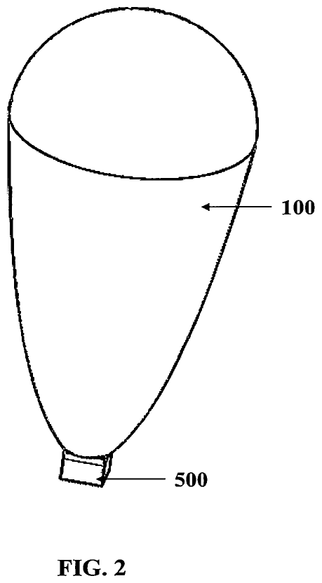

Referring to FIG. 2, the inflatable non-imaging solar concentrator 100 is assembled with the receiver package 500 which includes the photonic crystal solar spectrum splitter and the integrated circuitry solar cells to form the CPV system of the present invention.

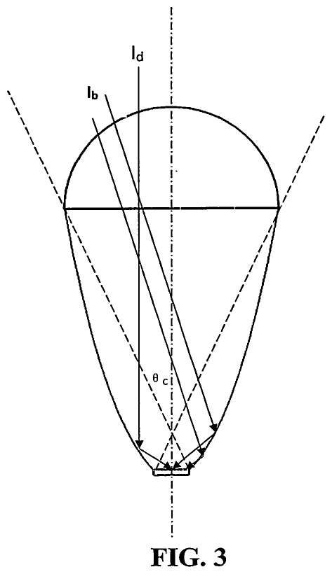

Referring to FIG. 3, incident sunlight including the beam light I_{b} and the diffuse light I_{d} will be concentrated onto the receiver, as long as they fall in the acceptance half-angle θ_{c} of the inflatable non-imaging solar concentrator of the present invention.

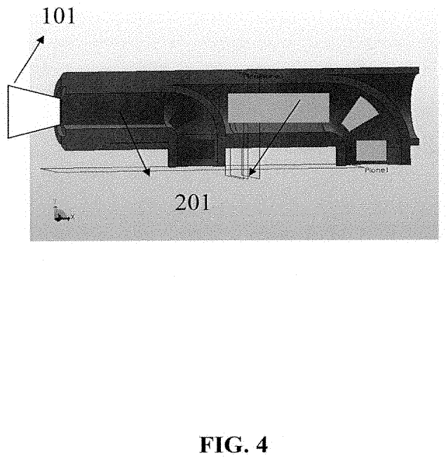

Referring to FIG. 4, the concentrated sunlight 101 coupled into the photonic crystal solar spectrum splitter is spliced into its components 201 and outputted to the integrated circuitry solar cells of the present invention.

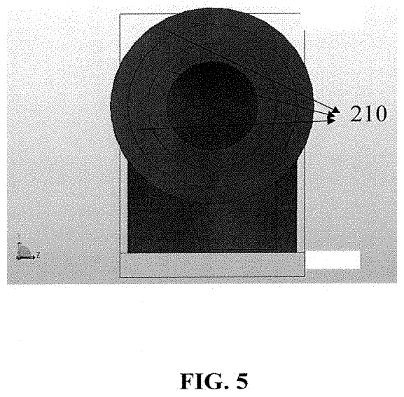

Referring to FIG. 5, the photonic crystal solar spectrum splitter is constructed with the photonic crystal waveguides 210 specified to confine the different components of the solar spectrum.

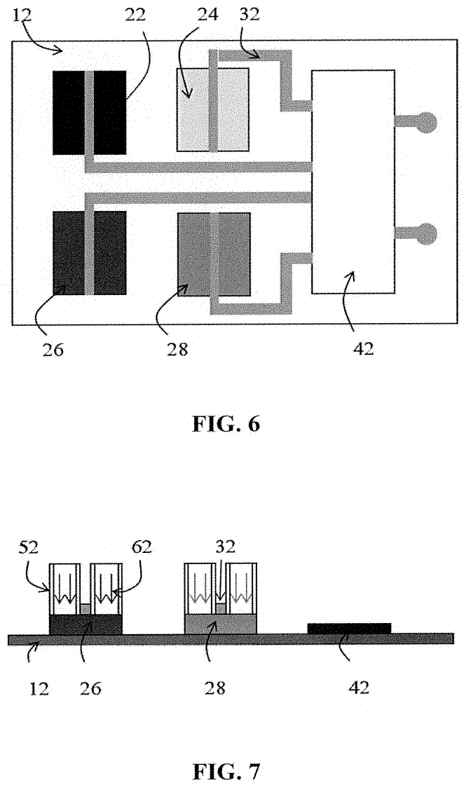

Referring to FIG. 6, the spliced components of the concentrated sunlight are channeled onto the elemental solar cells 22, 24, 26, 28 fabricated with band gap matched photovoltaic materials including perovskite materials with band gaps from 1.55 to 2.3 eV, CIGS materials, III-V group materials, IV group materials, and II-IV group materials with band gaps 0.25-1.55 eV and 2.3-4.0 eV, which are fabricated on the 2D substrate 12 and connected with interconnects 32 to output power to the power electronic circuit 42 for optimized total power output.

Referring to FIG. 7, the spliced components 62 are channeled onto the band gap matched elemental solar cells 26, 28 fabricated on the substrate 12 by the photonic crystal waveguides 52 which are the extension of the photonic crystal solar spectrum splitter, all elemental solar cells are connected with the interconnects 32 and then connected to the power electronic circuit 42.

In the present invention, the selection of band gap matched materials is focused on perovskite materials to address the issues of non-stability of this type of materials and take advantage of the low cost and high efficiency. But the other band gap matched materials such as III-V group materials and CIGS are also selected to convert the components such as UV to enhance the overall conversion efficiency of the integrated circuitry solar cells.

From the description above, a number of advantages of the inflatable non-imaging concentrator photonic crystal solar spectrum splitter perovskite integrated circuit concentrating photovoltaic system become evident. The adoption of the inflatable non-imaging solar concentrator enables large scale condensation of solar radiation and realizes the extremely low cost of CPV system. The employment of the synergistically combination of photonic crystal solar spectrum splitter and the integrated circuitry solar cells provides a new approach to realize ultra-high conversion efficiency of photovoltaic technologies. The incorporation of the perovskite solar cells into the integrated circuitry solar cells not only effectively addresses the non-stability, but also significantly reduces the cost and effectively raise the efficiency of the integrated circuitry receiver of the CPV system of the present invention.

In the preceding specification, various preferred embodiments have been described with reference to the accompanying drawings. It will, however, be evident that various other modifications and changes may be made thereto, and additional embodiments may be implemented, without departing from the broader scope of the invention as set forth in the claims that follow. The specification and drawings are accordingly to be regarded in an illustrative rather than restrictive sense.

Other embodiments of the invention will be apparent to those skilled in the art from consideration of the specification and practice of the invention disclosed herein. It is intended that the specification and examples be considered as exemplary only, with the true scope and spirit of the invention being indicated by the following claims.

I claim:

1. A Concentrating PhotoVoltaic (CPV) system, comprising: 1) an inflatable non-imaging Compound Parabolic Concentrator (CPC) solar concentrator; 2) a photonic crystal solar spectrum splitter; 3) a perovskite integrated circuitry solar cell package;
Wherein, the inflatable non-imaging CPC solar concentrator is optically coupled with the photonic crystal solar spectrum splitter; the photonic crystal solar spectrum splitter is optically coupled with the perovskite integrated circuitry solar cell package; when in operation, the incident sunlight is concentrated by the inflatable non-imaging CPC concentrator into the photonic crystal solar spectrum splitter; the photonic crystal solar spectrum splitter splits the concentrated sunlight into its components and channels them onto the elemental solar cells of the perovskite integrated circuitry solar cell package.

2. The photonic crystal solar spectrum splitter of claim 1, is made of hollow core photonic crystal waveguides specified to confine different components of solar spectrum; the photonic crystal waveguides are interpenetrated into a coaxial structure with the inner most hollow core photonic crystal waveguide bending and penetrating through the outer hollow core photonic crystal waveguides in sequence.

3. The perovskite integrated circuitry solar cell package of claim 1, is assembled by fabricating different elemental solar cells with different band gapes on a two dimensional substrate.

4. The perovskite integrated circuitry solar cell package of claim 1, wherein, some of the elemental solar cells are fabricated with perovskite materials with the matched band gaps to the spliced spectrum components with photon energy from 1.55 to 2.3 eV.

5. The perovskite integrated circuitry solar cell package of claim 1, wherein, some of the elemental solar cells are fabricated with photovoltaic materials such as III-V group materials, IV group materials, CIGS, and II-VI group materials, with the matched band gaps to the spliced spectrum components with photon energy from 0.25 to 1.55 eV.

6. The perovskite integrated circuitry solar cell package of claim 1, wherein, some of the elemental solar cells are fabricated with photovoltaic materials such as III-V group materials, IV group materials, CIGS, and II-VI group materials, with the matched band gaps to the spliced spectrum components with photon energy from 1.55 to 4.0 eV.
